(19) United States
(12) Patent Application Publication
(10) Pub. No.: US 2018/0260644 A1
(43) Pub. Date: Sep. 13, 2018

(54) Data Storage with In-situ String-Searching Capabilities Comprising Three-Dimensional Vertical Memory Arrays

(71) Applicant: Guobiao ZHANG, Corvallis, OR (US)

(72) Inventor: Guobiao ZHANG, Corvallis, OR (US)

(73) Assignee: HangZhou HaiCun Information Technology Co., Ltd., HangZhou (CN)

(21) Appl. No.: 15/975,748

(22) Filed: May 9, 2018

Related U.S. Application Data
(63) Continuation-in-part of application No. 15/452,728, filed on Mar. 7, 2017.

(30) Foreign Application Priority Data
Mar. 7, 2016 (CN) 201610127981.5
Mar. 7, 2017 (CN) 201710130887.X
Jun. 18, 2017 (CN) 201710461236.9
Jun. 19, 2017 (CN) 201710461243.9

(51) Int. Cl. G06K 9/00; G06F 17/30; G11C 5/02

(52) U.S. Cl. CPC G06K 9/00973; G11C 5/02; G06F 17/30985

(57) ABSTRACT

A preferred data storage with in-situ string-searching capabilities comprises a plurality of storage-processing units (SPU), with each SPU comprising at least a three-dimensional vertical memory (3D-M_{V}) array vertically stacked above a pattern-processing circuit. The 3D-M_{V} array stores at least a portion of big data. A search string from the input is sent to all SPUs, which perform string searching simultaneously.

### CROSS-REFERENCE TO RELATED APPLICATIONS

This application is a continuation-in-part of application “Distributed Pattern Processor Comprising Three-Dimensional Memory”, application Ser. No. 15/452,728, filed Mar. 7, 2017, which claims priorities from Chinese Patent Application No. 201610127981.5, filed Mar. 7, 2016; Chinese Patent Application No. 201710130887.X, filed Mar. 7, 2017, in the State Intellectual Property Office of the People's Republic of China (CN), the disclosures of which are incorporated herein by references in their entireties.

This application also claims priorities from Chinese Patent Application No. 201710461236.9, filed Jun. 18, 2017; Chinese Patent Application No. 201710461243.9, filed Jun. 19, 2017, in the State Intellectual Property Office of the People's Republic of China (CN), the disclosures of which are incorporated herein by references in their entireties.

### BACKGROUND

### 1. Technical Field of the Invention

The present invention relates to the field of integrated circuit, and more particularly to a storage device for big data.

### 2. Prior Art

Pattern matching and pattern recognition are the acts of searching a target pattern (i.e. the pattern to be searched) for the presence of the constituents or variants of a search pattern (i.e. the pattern used for searching). The match usually has to be “exact” for pattern matching, whereas it could be “likely to a certain degree” for pattern recognition. Unless explicitly stated, the present invention does not differentiate pattern matching and pattern recognition. They are collectively referred to as pattern processing. In addition, search patterns and target patterns are collectively referred to as patterns; pattern database refers to either search-pattern database, or target-pattern database.

Pattern processing has broad applications. Typical pattern processing includes string match, code match, speech recognition and image recognition. String match is widely used in big-data analytics (e.g. financial data mining, e-commerce data mining, bio-informatics). Examples of string match include regular expression matching, i.e. searching a regular expression in a database. Code match is widely used in anti-malware operations, for example, searching a malware pattern in a computer file, or checking if a network packet conforms to a set of network rules. Speech recognition matches a sequence of bits in the audio data with an acoustic model and/or a language model. Image recognition matches a sequence of bits in the image data with an image model.

The pattern database has become big: the search-pattern database (including all search patterns, e.g. a malware database, a rule database, an acoustic model database, a language model database, an image model database) is already big (on the order of GB); while the target-pattern database (including all target patterns, e.g. a user-data archive, a big-data database, an audio archive, an image archive) is even bigger (on the order of TB to PB, even EB). Pattern-processing for such a big database requires not only powerful processor, but also fast memory/storage. Unfortunately, the conventional von Neumann architecture cannot meet this requirement. In the von Neumann architecture, the processor is separated from the storage. The memory/storage (e.g. DRAM, solid-state drive, hard drive) only stores patterns, but does not process them. All pattern-processing is performed by an external processor (e.g. CPU, GPU). Because a “memory wall” exists between the processor and the memory/storage (i.e. the communication bandwidth between them is limited), it would take hours to even read a TB-scale data from a hard drive, let alone processing it. This poses as a bottleneck to perform pattern processing for a big pattern database.

### Objects and Advantages

It is a principle object of the present invention to expedite pattern processing.

It is a further object of the present invention to move pattern storage physically close to pattern processing.

It is a further object of the present invention to support massive parallelism for pattern processing.

It is a further object of the present invention to enhance network security.

It is a further object of the present invention to enhance computer security.

It is a further object of the present invention to improve the efficiency of rule enforcement.

It is a further object of the present invention to improve the efficiency of anti-malware operations.

It is a further object of the present invention to ensure computer integrity whenever a new malware is discovered.

It is a further object of the present invention to provide a computer storage with in-situ anti-malware capabilities at a reasonable cost.

It is a further object of the present invention to improve the efficiency of big-data analytics.

It is a further object of the present invention to provide a big-data storage with in-situ string-searching capabilities at a reasonable cost.

It is a further object of the present invention to improve the efficiency of speech recognition.

It is a further object of the present invention to provide an audio storage with in-situ audio-searching capabilities at a reasonable cost.

It is a further object of the present invention to improve the efficiency of image recognition.

It is a further object of the present invention to provide an image storage with in-situ image-searching capabilities at a reasonable cost.

In accordance with these and other objects of the present invention, the present invention discloses a distributed pattern storage-processing circuit comprising a three-dimensional memory (3D-M) array.

### SUMMARY OF THE INVENTION

The present invention discloses a distributed pattern storage-processing circuit comprising three-dimensional memory (3D-M) arrays. It not only stores patterns permanently, but also processes them with massive parallelism. The preferred distributed pattern storage-processing circuit is disposed on a pattern storage-processing die, which comprises a plurality of storage-processing units (SPU). Each SPU comprises at least a 3D-M array and a pattern-processing circuit. Stored in a same die as the pattern-processing circuit, patterns do not have to be fetched from an external storage. This avoids the bottleneck of “memory wall” faced by the von Neumann architecture. As used herein, the phrase “storage” refers to any permanent information store, wherein the phrase “permanent” is used in its broadest sense to mean any long-term storage.

In the preferred SPU, the 3D-M array is vertically stacked above the pattern-processing circuit. This type of integration is referred to as 3-D integration (as known as vertical integration). For the 3-D integration, the 3D-M array is communicatively coupled with the pattern-processing circuit through a plurality of contact vias, which are collectively referred to as inter-storage-processor (ISP) connections. As used herein, the phrase “communicatively coupled” is used in its broadest sense to mean any coupling whereby information may be passed from one element to another element.

The 3-D integration offers many advantages over the conventional 2-D integration (also known as horizontal integration), where the memory array and the processing circuit are placed side-by-side on the substrate of a processor die.

First of all, because the 3-D integration moves the 3D-M array above the pattern-processing circuit, the footprint of the SPU is the larger one of the two. In contrast, the footprint of a 2D-integrated processor die is the sum of the two. Hence, the SPU of the present invention is much smaller. With a small SPU, the preferred pattern storage-processing die comprises a large number of SPUs, typically on the order of thousands to tens of thousands. Because all SPUs can perform pattern processing simultaneously, the preferred pattern storage-processing circuit supports massive parallelism.

Secondly, because the 3-D integration moves the 3D-M array above the pattern-processing circuit, the 3D-M array is in close proximity to the pattern-processing circuit. As a result, the contact vias coupling them are short (microns) and numerous (thousands). This leads to fast ISP-connections, which have a shorter access time and a larger bandwidth than the 2-D integration. For the 2-D integration, because the memory array is far away from the processing circuit, the wires coupling them are long (hundreds of microns) and few (e.g. 64-bit).

Lastly, although the peripheral circuits of the 3D-M arrays are formed on the substrate, they only occupy a small substrate area and most substrate area can be used to form the pattern-processing circuit. Because the peripheral circuits of the 3D-M arrays need to be formed anyway and the pattern-processing circuit can be manufactured at the same time, inclusion of the pattern-processing circuit adds little or no extra cost from the perspective of the 3D-M arrays.

Accordingly, the present invention discloses a distributed pattern storage-processing circuit, comprising: an input for transferring a first pattern; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a second pattern; said pattern-processing circuit is disposed on said substrate and performs pattern matching or pattern recognition between said first and second patterns; said 3D-M array and said pattern-processing circuit are communicatively coupled by a plurality of contact vias.

### BRIEF DESCRIPTION OF THE DRAWINGS

FIG. 1 is a circuit block diagram of a preferred pattern storage-processing die;

FIGS. 2A-2C are circuit block diagrams of three preferred storage-processing units (SPU);

FIGS. 3A-3C are cross-sectional views of three preferred SPUs;

FIG. 4 is a perspective view of a preferred SPU;

FIGS. 5A-5C are substrate layout views of three preferred SPUs;

FIG. 6 summarizes the configurations of the preferred SPUs for different applications.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. Throughout the specification, the symbol “/” means “and/or”.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

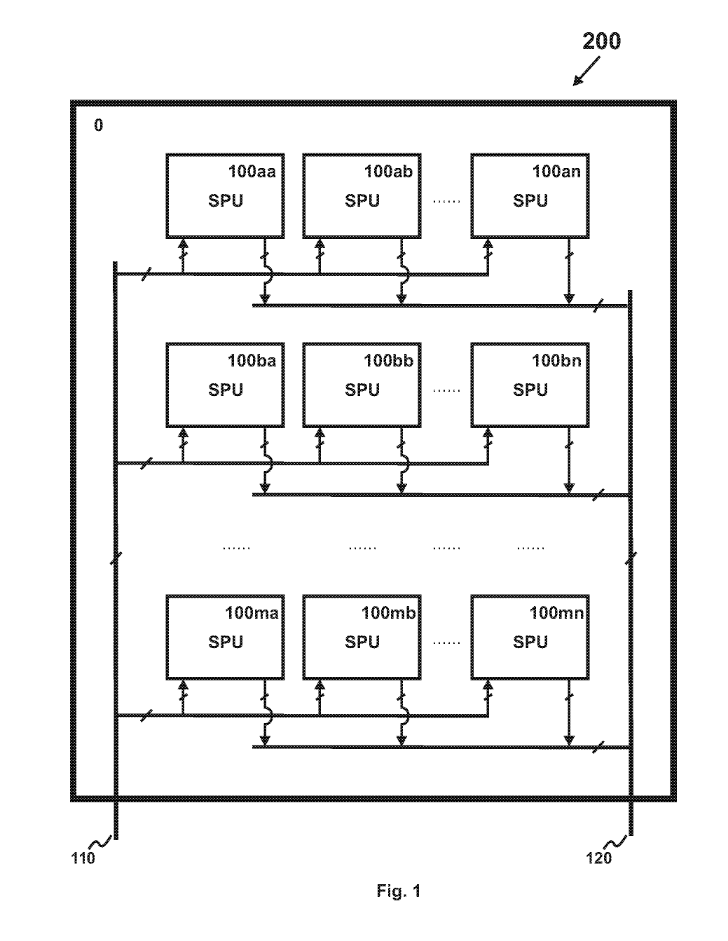

Referring now to FIG. 1, a preferred pattern storage-processing die 200 is disclosed. It not only stores patterns permanently, but also processes them with massive parallelism. The preferred pattern storage-processing die 200 comprises a distributed pattern storage-processing circuit, which includes an array with m rows and n columns (m×n) of storage-processing units (SPU) 100aa-100mn. Each SPU is commutatively coupled with an input 110 and an output 120. The input 110 includes a first pattern, which could be a network packet, a computer data, a rule pattern, a malware pattern, or the like. In general, the preferred pattern storage-processing die 200 comprises thousands to tens of thousands of SPUs 100aa-100mn. When the first pattern is fed to the input 110, it is sent to all SPUs 100aa-100mn, which perform pattern processing on the first pattern simultaneously. As a result, the preferred pattern storage-processing die 200 supports massive parallelism.

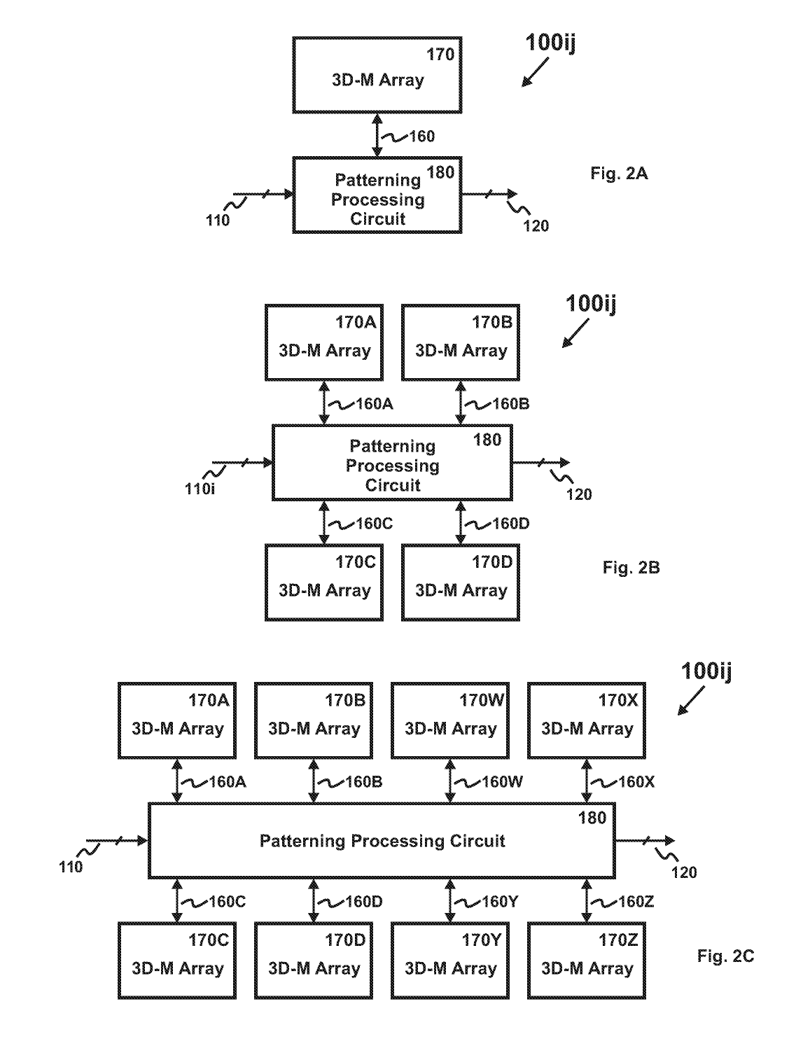

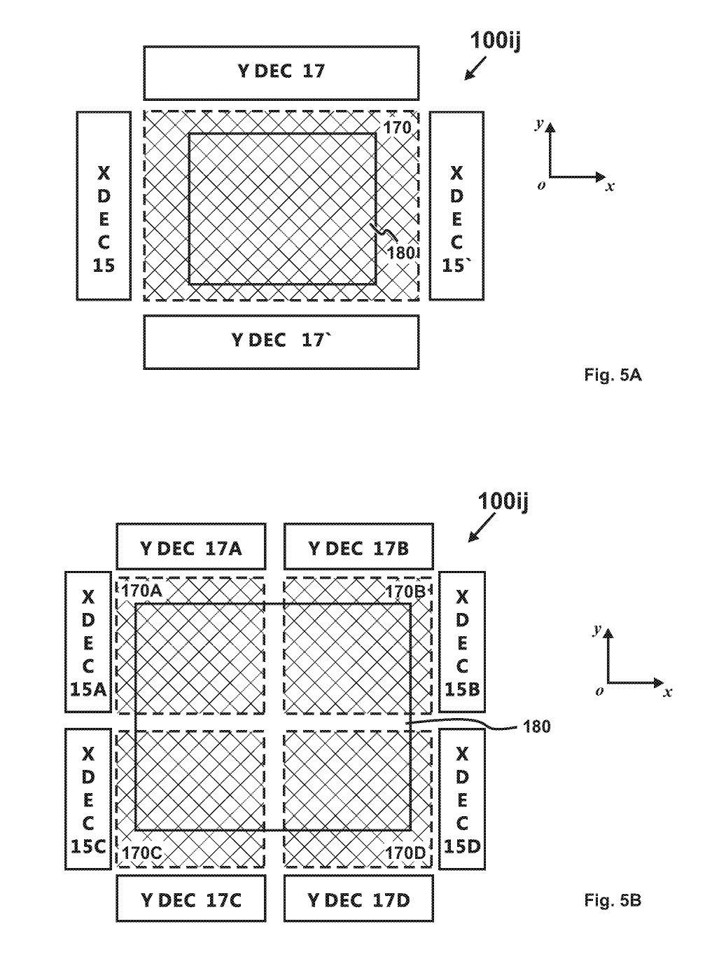

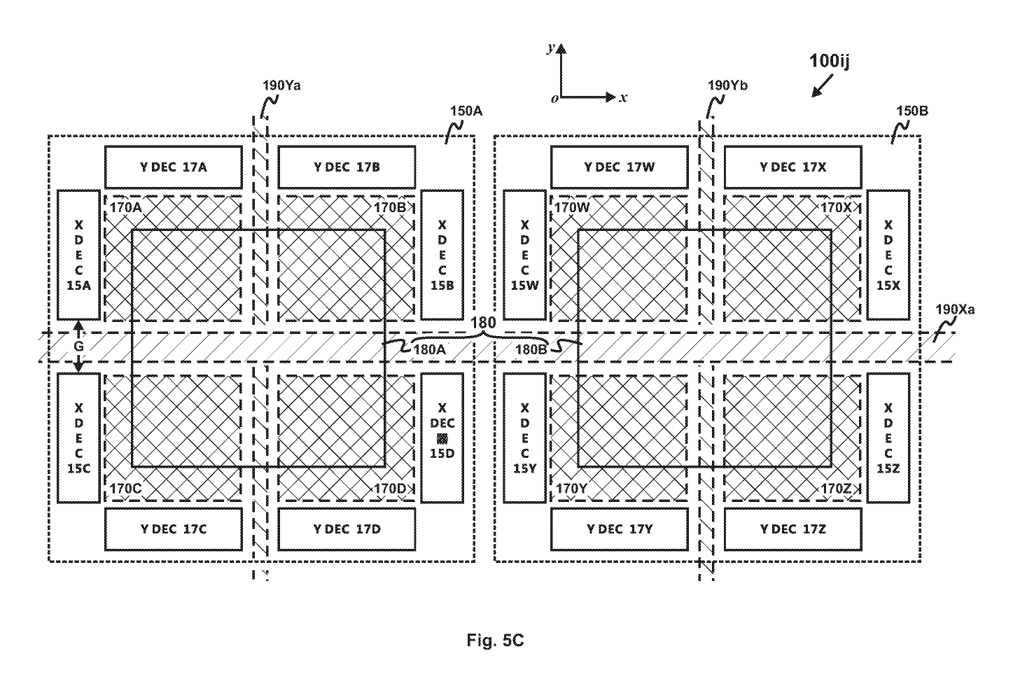

FIGS. 2A-2C discloses three preferred SPUs 100ij. Each SPU 100ji comprises a pattern-processing circuit 180 and at least a 3D-M array 170 (or, 170A-170D, 170W-170Z), which are communicatively coupled through inter-storage-processor (ISP) connections 160 (or, 160A-160D, 160W-160Z). The 3D-M array 170 stores at least a second pattern, which is compared against the first pattern from the input 110 during pattern processing. In these embodiments, the pattern-processing circuit 180 serves different number of 3D-M arrays. In the first embodiment of FIG. 2A, the pattern-processing circuit 180 serves one 3D-M array 170. In the second embodiment of FIG. 2B, the pattern-processing circuit 180 serves four 3D-M arrays 170A-170D. In the third embodiment of FIG. 2C, the pattern-processing circuit 180 serves eight 3D-M array 170A-170D, 170W-170Z. As will become apparent in FIGS. 5A-5C, the more 3D-M arrays it serves, a larger area and a better function will the SPU 100ij have.

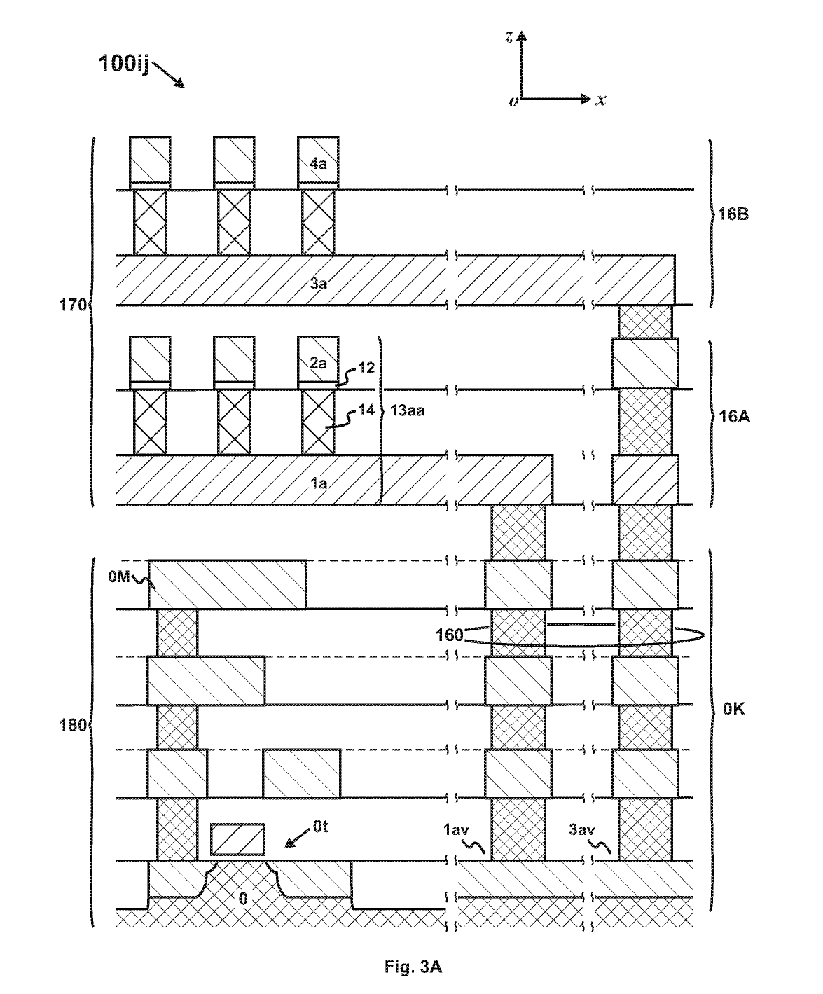

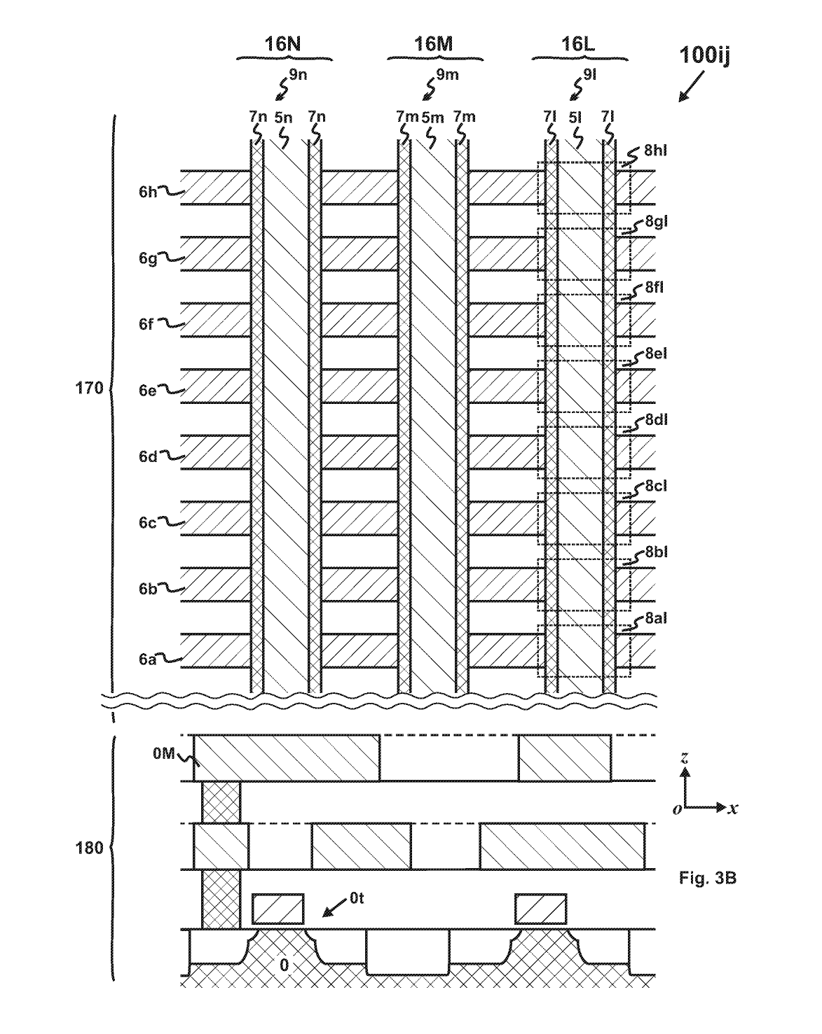

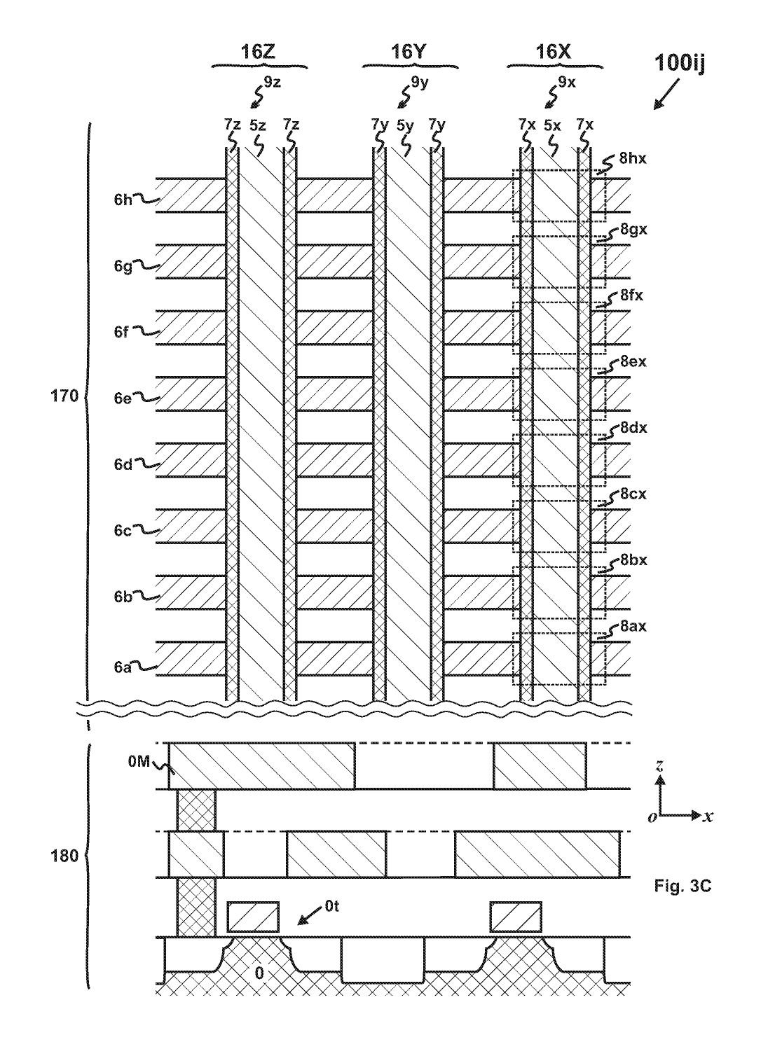

Referring now to FIGS. 3A-3C, preferred SPUs 100ij comprising 3D-M arrays 170 are shown. The 3D-M is a monolithic semiconductor memory whose memory cells are disposed in three-dimensional (3-D) space. Being non-volatile, the data in most 3D-M's are permanently stored. The 3D-M can be categorized into three-dimensional printed memory (3D-P) and three-dimensional writable memory (3D-W).

The data in the 3D-P are recorded using a printing method during manufacturing. These data are fixedly recorded and cannot be changed after manufacturing. The printing methods include photo-lithography, nano-imprint, e-beam lithography, DUV lithography, and laser-programming, etc. A common 3D-P is three-dimensional mask-programmed read-only memory (3D-MPROM), whose data are recorded by photo-lithography.

On the other hand, the data in the 3D-W are writable (or, electrically programmable). Based on the number of programmings allowed, a 3D-W can be categorized into three-dimensional one-time-programmable memory (3D-OTP) and three-dimensional multiple-time-programmable memory (3D-MTP, including 3-D re-programmable memory). The 3D-OTP has been mass-produced. It can be used to store search patterns (e.g. malware patterns, rule patterns, acoustic models, language models, image models), because search patterns are generally only added but not modified. The 3D-MTP is a general-purpose memory. It can be used to store target patterns (e.g. network packet, computer data, data from a big-data database, audio data, image data). Common 3D-MTP includes 3D-XPoint and 3D-NAND. Other 3D-W's include memristor, resistive random-access memory (RRAM or ReRAM), phase-change memory, programmable metallization cell (PMC), conductive-bridging random-access memory (CBRAM), and the like.

Based on the direction of address lines, the 3D-M can be further categorized into three-dimensional horizontal memory (3D-M_{H}) and three-dimensional vertical memory (3D-M_{V}). In a 3D-M_{H}, a horizontal memory level is first formed by a plurality of memory cells, before multiple memory levels are vertically stacked on the substrate to form a 3D-M structure. One well-known example of the 3D-M_{H} is 3D-XPoint. On the other hand, in a 3D-M_{V}, a vertical memory string is first formed by a plurality of memory cells, before multiple memory strings are horizontally disposed on the substrate to form a 3D-M structure. One well-known example of the 3D-M_{V} is 3D-NAND. In other words, all address lines in a 3D-M_{H} array are horizontal, whereas at least one set of address lines in a 3D-M_{V} array are vertical. As used herein, “horizontal” and “vertical” are the directions with respect to the surface of the substrate 0.

The preferred SPU 100ij of FIG. 3A comprises a 3D-M_{H} array. Within the 3D-M_{H} array, all address lines are oriented horizontally (i.e. in a direction parallel with the surface of the substrate 0). The preferred SPU 100ij further comprises a substrate circuit OK formed on the substrate 0. A first memory level 16A is stacked above the substrate circuit OK, with a second memory level 16B stacked above the first memory level 16A. The substrate circuit OK includes the peripheral circuits of the memory levels 16A, 16B and the pattern-processing circuit 180. It comprises transistors 0t and the associated interconnect 0M. Each of the memory levels (e.g. 16A, 16B) comprises a plurality of first address-lines (i.e. y-lines, e.g. 2a, 4a), a plurality of second address-lines (i.e. x-lines, e.g. 1a, 3a) and a plurality of 3D-M cells (e.g. 13aa). The first and second memory levels 16A, 16B are coupled to the substrate circuit OK through contact vias 1av, 3av, respectively. Coupling the 3D-M array 170 and the pattern-processing circuit 180, the contacts vias 1av, 3av are collectively referred to as inter-storage-processor (ISP) connections 160.

The 3D-M cell 13aa in FIG. 3A is a 3D-W cell. It comprises a programmable layer 12 and a diode layer 14. The programmable layer 12 could be an antifuse layer (used for 3D-OTP) or a re-programmable layer (used for 3D-MTP). The diode layer 14 is broadly interpreted as any layer whose resistance at the read voltage is substantially lower than when the applied voltage has a magnitude smaller than or polarity opposite to that of the read voltage. The diode could be a semiconductor diode (e.g. p-i-n silicon diode), a metal-oxide (e.g. TiO₂) diode, or the like. In some embodiments, the 3D-M cell 13aa does not have a separate diode layer 14 by, for example, forming a built-in diode between two address lines 1a, 2a. It should be apparent to those skilled in the art that other variations of the 3D-M cell 13aa are possible. For example, the 3D-M cell 13aa may comprise a thin-film transistor (TFT).

The preferred SPU 100ij of FIGS. 3B-3C comprises a 3D-M_{V} array. Within the 3D-M_{V} array, at least one set of the address lines are oriented vertically (i.e. in a direction perpendicular to the surface of the substrate 0). Because it can have more memory cells stacked in the vertical direction (e.g. 32-cells, 64-cells, 96-cells, or even more cells, on each memory string), the 3D-M_{V} can store more patterns than a 3D-M_{H} for a given die area.

The preferred 3D-M_{V} array 170 in FIG. 3B is based on vertical diodes or diode-like devices. The 3D-M_{V} array 170 comprises a plurality of vertical memory strings 16L-16N placed side-by-side on the pattern-processing circuit 180. Each memory string (e.g. 16L) comprises a plurality of vertically stacked memory cells (e.g. 8al-8hl). The 3D-M_{V} array 170 and the pattern-processing circuit 180 are coupled through ISP-connections 160 including a plurality of contact vias (not shown in this figure). The 3D-M_{V} array 170 comprises a plurality of horizontal address lines (x-lines) 6a-6h which are stacked one above another and separated by insulating layers. The horizontal address lines 6a-6h comprise conductive materials such as metallic materials or heavily doped semiconductor materials. After etching through the horizontal address lines 6a-6h to form holes 9l-9n, the sidewalls of these holes 9a-9c are coated with a programmable layers 7l-7n, which could be one-time programmable (OTP, e.g. an antifuse layer) or multiple-time programmable (MPT, e.g. a resistive RAM layer). The holes 9l-9n in FIG. 3B are then filled with conductive materials to form vertical address lines (z-lines) 5l-5n. The conductive materials comprise metallic materials or heavily doped semiconductor materials.

Located at the intersections of the word lines 6a-6h and the bit line 5l, the memory cells 8al-8hl comprise two-terminal devices such as diodes or diode-like devices. Because the address lines 5l-5n are vertical, these diodes or diode-like devices are vertical diodes or diode-like devices. They can minimize interference between memory cells. The diode action can be enhanced if the address lines 6a-6h and the address lines 5l-5n are oppositely doped (to form a semiconductor diode), or, one address line comprises metallic materials while the other address line comprises semiconductor materials (to form a Schottky diode). Alternatively, the sidewalls of the holes 9l-9n can be further coated with a diode layer (also known as a selection layer, a steering layer, a quasi-conductive layer) to enhance the diode action (not shown in this figure). It should be apparent to those skilled in the art that other variations of diodes or diode-like devices can be used in the 3D-M_{V} array 170.

The preferred 3D-M_{V} array 170 in FIG. 3C is based on vertical transistors or transistor-like devices. The 3D-M_{V} array 170 comprises a plurality of vertical memory strings 16X-16Y placed side-by-side on the pattern-processing circuit 180. Each memory string (e.g. 16X) comprises a plurality of vertically stacked memory cells (e.g. 8ax-8hx). The 3D-M_{V} array 170 and the pattern-processing circuit 180 are coupled through ISP-connections 160 including a plurality of contact vias (not shown in this figure). The 3D-M_{V} array 170 comprises a plurality of horizontal address lines (x-lines) 6a-6h which are stacked one above another and separated by insulating layers. The horizontal address lines 6a-6h comprise conductive materials such as metallic materials or heavily doped semiconductor materials. After etching through the horizontal address lines 6a-6h to form holes 9x-9z, the sidewalls of the holes 9x-9z are coated with an ONO layer, i.e. a first silicon oxide layer (as a gate insulating layer), a silicon nitride layer (as a charge trapping layer) and a second silicon oxide layer (as a tunneling layer). The holes 9x-9z are then filled with semiconductive materials to form vertical address lines (z-lines) 5x-5z. The semiconductive materials comprise lightly doped semiconductor materials.

Located at the intersections of the word lines 6a-6h and the bit line 5x, the memory cells 8ax-8hx comprise three-terminal devices such as transistors or transistor-like devices. The horizontal address lines 6a-6h act as the transistor gates, while the vertical address lines 5x-5z act as the transistor channels. Because the channels 5x-5z are vertical, these transistors or transistor-like devices are vertical transistors or transistor-like devices. When all transistors in the memory cells 8ax-8hx on a vertical memory string 16X are turned on, the vertical address line 5x conducts current; otherwise, the vertical address line 5x blocks current. It should be apparent to those skilled in the art that other variations of vertical transistors or transistor-like devices can be used in the 3D-M_{V} array 170.

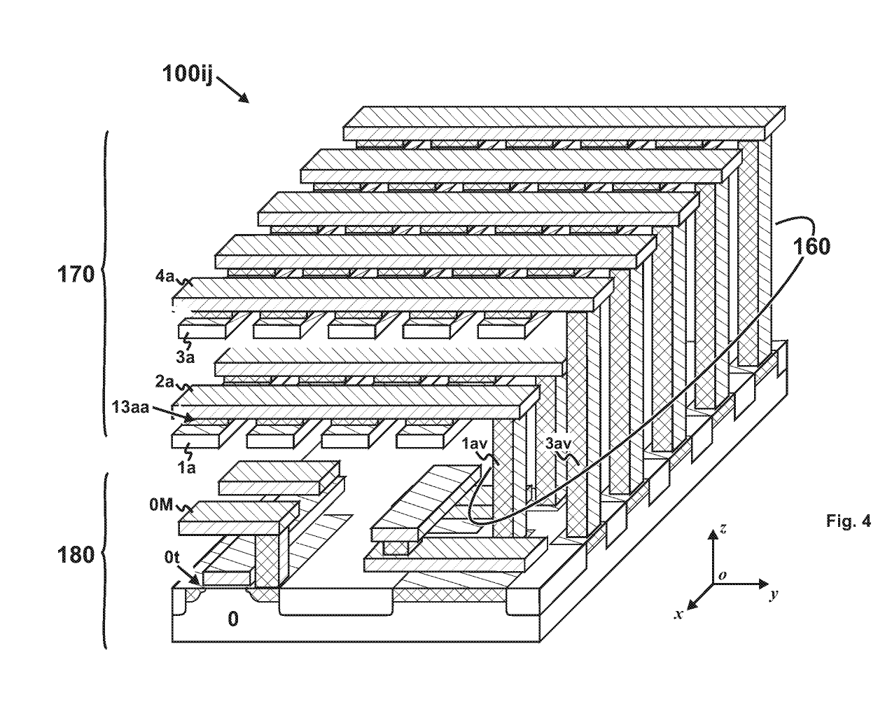

Referring now to FIG. 4, a perspective view of the SPU 100ij is shown. The 3D-M array 170 are vertically stacked above the pattern-processing circuit 180, which is located on the substrate 0 and at least partially covered by the 3D-M array 170. The ISP-connections 160 couples the 3D-M array 170 with the pattern-processing circuit 180. Because the contact vias 1av, 3av are short (microns) and numerous (thousands), this leads to fast ISP-connections 160, which have a shorter access time and a larger bandwidth than the conventional 2-D integration. In addition, the footprint of the SPU 100ij is the larger one of the 3D-M array 170 and the pattern-processing circuit 180, which is much smaller than the conventional 2-D integration.

Referring now to FIGS. 5A-5C, the substrate layout views of three preferred SUPs 100ij are shown. The embodiment of FIG. 5A corresponds to the SPU 100iji of FIG. 2A. The pattern-processing circuit 180 serves one 3D-M array 170. It is fully covered by the 3D-M array 170. The 3D-M array 170 has four peripheral circuits, including x-decoders 15, 15′ and y-decoders 17, 17′. The pattern-processing circuit 180 is bound by these four peripheral circuits. Because the 3D-M array 170 is stacked above the substrate 0, but not formed on the substrate 0, its projection on the substrate 0, not the 3D-P array itself, is shown in the area enclosed by dash line.

In this preferred embodiment, because it is bound by four peripheral circuits, the area of the pattern-processing circuit 180 must be smaller than that of the 3D-M array 170. As a result, the pattern-processing circuit 180 has limited functions. It is more suitable for simple pattern processing (e.g. string match, or code match). Apparently, complex pattern processing (e.g. speech recognition, image recognition) requires a larger area to facilitate the layout of the pattern-processing circuit 180. FIGS. 5B-5C discloses two preferred pattern-processing circuits 180 with larger areas and more functions.

The embodiment of FIG. 5B corresponds to the SPU 100ij of FIG. 2B. The pattern-processing circuit 180 serves four 3D-M arrays 170A-170D. Each 3D-M array (e.g. 170) has two peripheral circuits (e.g. x-decoder 15A and y-decoder 17A). Below these four 3D-M arrays 170A-170D, the pattern-processing circuit 180 can be formed. Apparently, the pattern-processing circuit 180 of FIG. 5B could be four times as large as that of FIG. 5A. It can perform complex pattern-processing functions.

The embodiment of FIG. 5C corresponds to the SPU 100ij of FIG. 2C. The pattern-processing circuit 180 serves eight 3D-M arrays 170A-170D, 170W-170Z. These 3D-M arrays are divided into two sets: a first set 150A includes four 3D-M arrays 170A-170D, and a second set 150B includes four 3D-M arrays 170W-170Z. Below the four 3D-M arrays 170A-170D of the first set 150A, a first component 180A of the pattern-processing circuit 180 is formed. Similarly, below the four 3D-M array 170W-170Z of the second set 150B, a second component 180B of the pattern-processing circuit 180 is formed. In this embodiment, adjacent peripheral circuits (e.g. adjacent x-decoders 15A, 15C, or, adjacent y-decoders 17A, 17B) are separated by physical gaps (e.g. G). These physical gaps allow the formation of the routing channel 190Xa, 190Ya, 190Yb, which provide coupling between different components 180A, 180B, or between different pattern-processing circuits. Apparently, the pattern-processing circuit 180 of FIG. 5C could be eight times as large as that of FIG. 5A. It can perform more complex pattern-processing functions.

It should be noted that, in some embodiments of the present invention, the pattern-processing circuit 180 just performs partial pattern processing. For example, the pattern-processing circuit 180 only performs a preliminary pattern processing (e.g. string match, or code match). After being filtered by the simple pattern processing, the remaining patterns are sent to an external processor (e.g. CPU, GPU) to complete the full pattern processing. Because a majority of patterns are filtered by the preliminary pattern processing, the patterns outputted from the pattern-processing circuit 180 are far fewer than the patterns in the preferred storage. This can alleviate the bandwidth requirement on the output 120.

The preferred pattern storage-processing circuits 200 can be either processor-like or storage-like. The processor-like pattern storage-processing circuit is referred to as a pattern processor with embedded pattern storage, whereas the storage-like pattern storage-processing circuit is referred to as a pattern storage with in-situ pattern-processing capabilities.

[A] Pattern Processor with Embedded Pattern Storage

The preferred pattern processor with embedded pattern storage acts like a processor. It checks the input data (i.e. the target pattern) against a search-pattern database. To be more specific, the 3D-M array 170 in the SPU 100ij stores at least a search pattern (e.g. a malware pattern, a rule pattern, an acoustic/language model, or an image model) from a search-pattern database (e.g. a malware database, a rule database, an acoustic/language model database, or an image model database), while the input 110 includes at least a target pattern (e.g. network packet, computer data, data in a big-data database, audio data, or image data). In the meantime, the pattern-processing circuit 180 performs pattern matching or pattern recognition between the search pattern and the target pattern. With massive parallelism and fast ISP-connections, the preferred pattern processor with embedded pattern storage can achieve a fast speed and a better efficiency.

Accordingly, the present invention discloses a pattern processor with embedded pattern storage, comprising: an input for transferring a target pattern; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a search pattern; said pattern-processing circuit is disposed on said substrate and performs pattern matching or pattern recognition between said search pattern and said target pattern; said 3D-M array and said pattern-processing circuit are communicatively coupled by a plurality of contact vias.

[B] Pattern Storage with In-Situ Pattern-Processing Capabilities

The preferred pattern storage with in-situ pattern-processing capabilities acts like a storage. Its primary purpose is to permanently store target patterns (e.g. computer data, big data, audio data, or image data), with a secondary purpose of searching the target patterns for a search pattern (e.g. a malware pattern, a rule pattern, an acoustic/language model, or an image model). To be more specific, the 3D-M array 170 in the SPU 100ij permanently stores at least a target pattern, while the input 110 include at least a search pattern. In the meantime, the pattern-processing circuit 180 performs pattern matching or pattern recognition between the search pattern and the target pattern.

Just like the flash memory, a plurality of pattern storage dice with in-situ pattern-processing capabilities can be packaged into a storage card (e.g. an SD card, a TF card) or a solid-state drive (SSD). They can be used to store mass user data (e.g. in a user-data archive). As each SPU 100ij in each storage die 200 has its own pattern-processing circuit 180, the pattern-processing circuit 180 only needs to process the user data stored in the 3D-M array 170 of the same SPU 100ij. As a result, no matter how large the capacity of a storage card (or, a solid-state drive) is, the processing time for the whole storage card (or, the whole solid-state drive) is similar to that for a single SPU 100ij. This is much faster and more efficient than a conventional storage.

Another benefit of the preferred pattern storage is its low cost. Although the peripheral circuits of the 3D-M arrays 170 are formed on the substrate 0, they only occupy a small substrate area and most substrate area can be used to form the pattern-processing circuit 180 (FIGS. 5A-5C). Because the peripheral circuits of the 3D-M arrays 170 need to be formed anyway and the pattern-processing circuit 180 can be manufactured at the same time, inclusion of the pattern-processing circuit 180 to a conventional 3D-M die adds little or no extra cost.

Accordingly, the present invention discloses a pattern storage with in-situ pattern-processing capabilities, comprising: an input for transferring a search pattern; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a target pattern; said pattern-processing circuit is disposed on said substrate and performs pattern matching or pattern recognition between said search pattern and said target pattern; said 3D-M array and said pattern-processing circuit are communicatively coupled by a plurality of contact vias.

### Applications

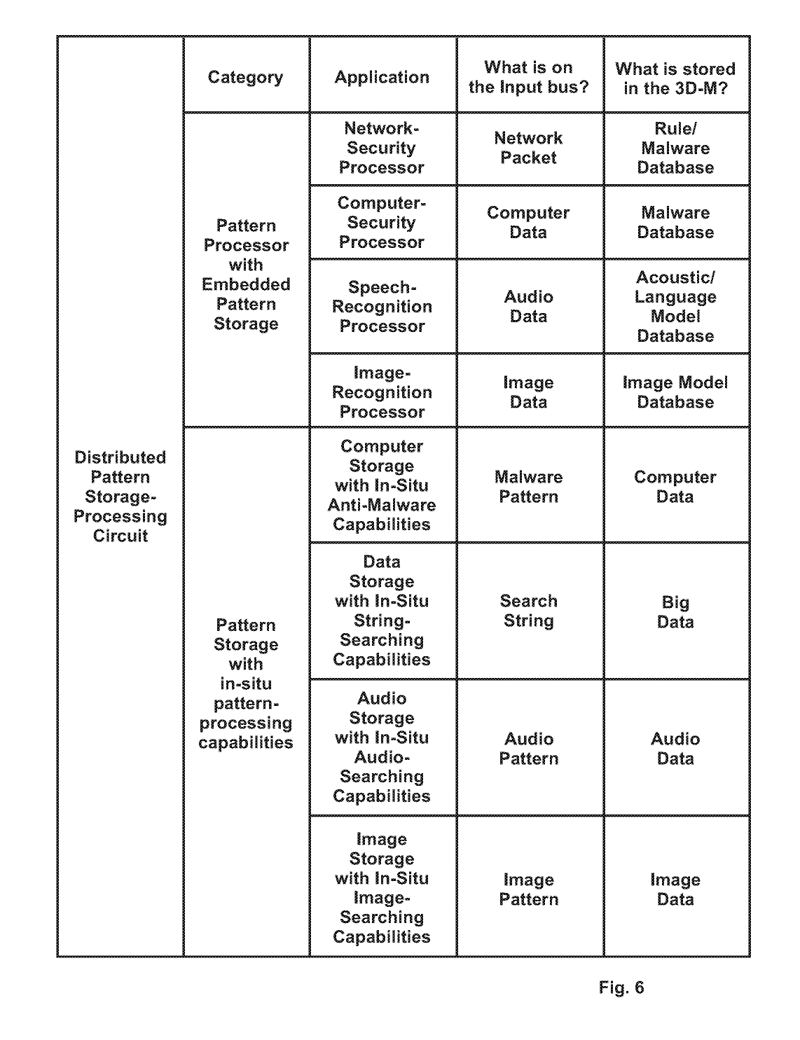

In the following paragraphs, several applications of the present invention are disclosed. The fields of applications are information security, big-data analytics, speech recognition and image recognition. Examples of the applications include: A) Network-security processor; B) Computer-security processor; C) Computer storage with in-situ anti-malware capabilities; D) Data storage with in-situ string-searching capabilities; E) Speech-recognition processor; F) Audio storage with in-situ audio-searching capabilities; G) Image-recognition processor; H) Image storage with in-situ image-searching capabilities. The configurations of the preferred SPUs for different applications are listed in FIG. 6.

A) Network-Security Processor

With the proliferation of the Internet, network security becomes great concerns. Network security does as its title explains: it secures the network, as well as protecting and overseeing operations being done. Network security can be generally categorized into rule enforcement and anti-malware, although there is considerable overlap between the two.

Rules (also known as network rules, security rules, etc.) include policies and practices adopted to prevent and monitor unauthorized access, misuse, modification, or denial of a computer network and network-accessible resources. During rule enforcement, a network packet is compared against rule patterns in a rule database (also known as rule pattern database, etc.).

Malware, short for malicious software, is any software used to disrupt computer operation, gather sensitive information, or gain access to private computer systems. During the anti-malware operation, a network packet is compared against malware patterns (also known as malware signatures, virus patterns, virus signatures, etc.) in a malware database. Unless explicitly stated, the present invention does not differentiate “malware” and “virus”. They are used interchangeably.

The basic operations in rule enforcement and anti-malware are pattern matching and/or pattern recognition. Nowadays, both rule database and malware database have become large: the number of network rules has reached tens of thousands, soon to hundreds of thousands; whereas, the number of malwares has reached hundreds of thousands, soon to millions. Pattern processing for such large rule/malware database requires not only a powerful processor, but also a fast rule/malware storage. Unfortunately, a conventional network-security system cannot meet these requirements. Because it has a limited number (tens to hundreds) of cores, a typical processor (CPU, GPU, etc.) can simultaneously perform only a limited number (tens to hundreds) of pattern processing. Furthermore, because the processor is physically separated from the rule/malware storage in a von Neumann architecture, the “memory wall” between them would cause a long delay when the processor fetches rule/malware patterns from the rule/malware storage. As a result, the performance of the conventional network-security system is poor.

To address this issue, the present invention discloses a network-security processor for enhancing network security. It is installed in a network, either as a standalone processor, or embedded in a network processor or other network appliances. The preferred network-security processor takes the form of a pattern processor with embedded pattern storage. To be more specific, the 3D-M array 170 permanently stores at least a rule/malware pattern from a rule/malware database, while the input 110 includes at least an incoming network packet. In the meantime, the pattern-processing circuit 180 performs pattern matching or pattern recognition between the rule/malware pattern and the network packet. With massive parallelism and fast ISP-connections, the preferred network-security processor can perform rule enforcement and anti-malware operations fast and efficiently.

Accordingly, the present invention discloses a network-security processor, comprising: an input for transferring at least a network packet; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a rule/malware pattern; said pattern-processing circuit is disposed on said semiconductor substrate and performs pattern matching or pattern processing between said rule/malware pattern and said network packet; said 3D-M array and said pattern-processing circuit are communicatively coupled by a plurality of contact vias.

B) Computer-Security Processor

Computer security is the protection of computer systems from the theft or damage to their software or information, as well as from disruption or misdirection of the services they provide. As used herein, a computer is any device with a processor and a memory. Such devices can range from non-networked standalone devices as simple as calculators, to networked computing devices such as smart-phones and tiny devices as part of the Internet of Things (IoT).

An important aspect of computer security is anti-malware. During the anti-malware operation, at least a portion of the data stored in the computer (e.g. a document, a file, a message, a packet or stream of data, or the like) is scanned against the malware patterns from a malware database. Because the conventional processor has a limited number of cores and the malware database (which contains hundreds of thousands of malware patterns) is stored away from the processor, the performance of the conventional computer-security system is poor.

To address this issue, the present invention discloses a computer-security processor for enhancing computer security. It is installed in a computer, either as a standalone processor, or embedded in a central processing unit (CPU) or other computer components. The preferred computer-security processor takes the form of a pattern processor with embedded pattern storage. To be more specific, the 3D-M array 170 permanently stores at least a malware pattern from a malware database, while the input 110 includes at least a portion of computer data. In the meantime, the pattern-processing circuit 180 performs pattern matching or pattern recognition between the malware pattern and the computer data. With massive parallelism and fast ISP-connections, the preferred computer-security processor can perform anti-malware operations fast and efficiently.

Accordingly, the present invention discloses a computer-security processor, comprising: an input for transferring at least a portion of computer data; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a malware pattern; said pattern-processing circuit is disposed on said semiconductor substrate and performs pattern matching or pattern processing between said malware pattern and said computer data; said 3D-M array and said pattern-processing circuit are communicatively coupled by a plurality of contact vias.

C) Computer Storage with In-Situ Anti-Malware Capabilities

The conventional computer-security system has an issue whenever a new malware is discovered. Although the malware database can be instantly updated to ensure the integrity of future data (i.e. the data to be stored), the integrity of existing data (i.e. data stored before the discovery of the new malware) cannot be guaranteed. This is because the existing data might have been infected by this newly-discovered malware. To ensure their integrity, all existing data need to be screened against the newly-discovered malwares. This is challenging for the conventional computer, whose storage (e.g. hard-disk drive, solid-state drive) is “dumb” and does not have any anti-malware capabilities per se. When a new malware is discovered, all existing data need to be read out from the storage and sent to a processor for malware screening. It takes hours to read out TBs of data and process them. Thus, the conventional computer-security system cannot efficiently screen the existing data when a new malware is discovered.

To address this issue, the present invention discloses a computer storage with in-situ anti-malware capabilities. It is primarily a computer storage, with anti-malware as its secondary function. Compared with prior art, the preferred computer storage is “smarter” and has in-situ anti-malware capabilities. The preferred computer storage takes the form of a pattern storage with in-situ pattern-processing capabilities. To be more specific, the 3D-M array 170 permanently stores at least a portion of computer data, while the input 110 includes at least a malware pattern from a malware database. In the meantime, the pattern-processing circuit 180 performs pattern matching or pattern recognition between the malware pattern and selected computer data. With massive parallelism and fast ISP-connections, the preferred computer storage can perform anti-malware operations on its data fast and efficiently.

Accordingly, the present invention discloses a computer storage with in-situ anti-malware capabilities, comprising: an input for transferring at least a malware pattern; a semiconductor substrate having transistors thereon; a plurality of storage-processing units (SPU) coupled with said input, each of said SPUs comprising a pattern-processing circuit and at least a three-dimensional memory (3D-M) array, wherein said 3D-M array is stacked above said pattern-processing circuit and stores at least a portion of computer data; said pattern-processing circuit is disposed on said semiconductor substrate and performs pattern matching or pattern processing between said malware pattern and said computer data; said 3D-M array and said pattern-processing circuit are communicatively coupled by a plurality of contact vias.

D) Data Storage with In-Situ String-Searching Capabilities

Big data is a term for data sets that are so large or complex that conventional data processing methods are inadequate to deal with them. Big data philosophy encompasses unstructured, semi-structured and structured data, however the main focus is on unstructured and semi-structure data. With high volume, high velocity and high variety, big-data analytics demand cost-effective and innovative forms of information processing.

An important aspect of big-data analytics is string searching. The basic string-searching operations are pattern matching and/or pattern recognition between a search string (or, a key word) and a data from a big-data database. Big data has become big: its “size” ranges from a few dozen of TBs to many PBs and is still growing. This makes it difficult to use a conventional computer to perform big-data analytics. Based on the von Neumann architecture, the storage and the processor of the conventional computer are separated. Because a conventional storage is “dumb”, i.e. without any data-analyzing capabilities per se, the data to be analyzed have to be read out from the storage first, which could take hours. Consequently, the von Neumann architecture is not suitable for big-data analytics. At present, big-data analytics generally requires tens, hundreds, or even thousands of servers.

To address this issue, the present invention discloses a data storage with in-situ string-searching capabilities. It is primarily a data storage, with string searching as its secondary function. Compared with prior art, the preferred data storage is “smarter” and has an in-situ string-searching capabilities. The preferred data storage takes the form of a pattern storage with in-situ pattern-processing capabilities. To be more specific, the 3D-M array 170 permanently stores at least a portion of big data, while the input 110 includes at least a search string. In the meantime, the pattern-processing circuit 180 performs pattern matching or pattern recognition between the search string and selected data.

The pattern-processing circuit 180 performs pattern matching and/or pattern recognition. It may take many forms. In one example, since a search string can be represented by a string of characters, the pattern-processing circuit 180 may comprise text-matching circuit, a string-matching circuit or a code-matching circuit. The string/text/code-matching circuits could be implemented by a content-addressable memory (CAM) or a comparator including XOR circuits. In another example, since a search string can be represented by a regular expression, the pattern-processing circuit 180 can be implemented by finite-state automata (FSA) circuits, which include non-deterministic FSA (NFA) circuits or deterministic FSA (DFA) circuits. It should be noted that, besides string searching, the pattern-processing circuit 180 may perform other functions, e.g. filtering, sorting, malware-screening, etc. With massive parallelism and fast ISP-connections, the preferred data storage can perform string searching on its data fast and efficiently.

The 3D-M_{V} has the largest storage density among all semiconductor memories. For example, because it can have more memory cells stacked in the vertical direction (e.g. 32-cells, 64-cells, 96-cells, or even more cells, on each memory string), the 3D-M_{V} can store more patterns than a 3D-M_{H} for a given die area. Hence, the 3D-M_{V} is particularly suitable for big-data storage. To stress the benefit of the 3D-M_{V}, the claims of the present invention are confined to the 3D-M_{V}.

Accordingly, the present invention discloses a data storage with in-situ string-searching capabilities, comprising: an input for transferring at least a search string; a semiconductor substrate having transistors thereon; a plurality of storage-processing units (SPU) coupled with said input, each of said SPUs comprising a pattern-processing circuit and at least a three-dimensional vertical memory (3D-M_{V}) array, wherein said 3D-M_{V} array is stacked above said pattern-processing circuit and stores at least a portion of data; said pattern-processing circuit is disposed on said semiconductor substrate and searches said search string in said portion of data; said 3D-M_{V} array and said pattern-processing circuit are communicatively coupled by a plurality of contact vias.

E) Speech-Recognition Processor

Speech recognition enables the recognition and translation of spoken language. It is primarily implemented through pattern recognition between an acoustic/language model and an audio data. The acoustic/language models collectively form an acoustic/language model database. Because the conventional processor has a limited number of cores and the acoustic/language model database is stored away from the processor, the performance of the conventional speech-recognition system is poor.

To address this issue, the present invention discloses a speech-recognition processor. It takes the form of a pattern processor with embedded pattern storage. To be more specific, the 3D-M array 170 store at least a portion of an acoustic/language model from an acoustic/language model database, while the input 110 include at least a portion of audio data acquired by at least an audio sensor. In the meantime, the pattern-processing circuit 180 performs pattern recognition between the acoustic/language model and the audio data.

Accordingly, the present invention discloses a speech-recognition processor, comprising: an input for transferring at least a portion of audio data; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a portion of an acoustic/language model; said pattern-processing circuit is disposed on said semiconductor substrate and performs pattern recognition between said acoustic/language model and said audio data; said 3D-M array and said pattern-processing circuit are communicatively coupled by a plurality of contact vias.

F) Audio Storage with In-Situ Audio-Searching Capabilities

It is highly desired to search an audio database for an audio pattern. The audio database includes a plurality of audio files. When it is to be stored permanently, the audio database becomes an audio archive. On the other hand, the audio pattern includes an audio segment such as a speech segment or a music segment. The audio pattern could also include an acoustic model or a language model. It is challenging to do audio-search for a conventional computer because of the von Neumann architecture.

To address this issue, the present invention discloses an audio storage with in-situ audio-searching capabilities. It takes the form of a pattern storage with in-situ pattern-processing capabilities. To be more specific, the 3D-M array 170 permanently stores at least a portion of audio data, while the input 110 includes at least a portion of an audio pattern. In the meantime, the pattern-processing circuit 180 performs pattern recognition between the audio pattern and the audio data. With massive parallelism and fast ISP-connections, the preferred audio storage can perform audio-searching operations on its audio data fast and efficiently.

Accordingly, the present invention discloses an audio storage with in-situ audio-searching capabilities, comprising: an input for transferring at least a portion of an audio pattern; a semiconductor substrate having transistors thereon; a plurality of storage-processing units (SPU) coupled with said input, each of said SPUs comprising a pattern-processing circuit and at least a three-dimensional memory (3D-M) array, wherein said 3D-M array is stacked above said pattern-processing circuit and stores at least a portion of audio data; said pattern-processing circuit is disposed on said semiconductor substrate and performs pattern recognition between said audio pattern and said audio data; said 3D-M array and said pattern-processing circuit are communicatively coupled by a plurality of contact vias.

G) Image-Recognition Processor

Image (e.g. still images, moving images, 3-D images) recognition (also known as computer vision, machine vision, image processing) determines if an image contains a specific object, feature, or activity. It is primarily implemented through pattern recognition between an image model and an image data. The image models collectively form an image model database. Because the conventional processor has a limited number of cores and the image model database is stored away from the processor, the performance of the conventional image-recognition system is poor.

To address this issue, the present invention discloses an image-recognition processor. It takes the form of a pattern processor with embedded pattern storage. To be more specific, the 3D-M array 170 store at least a portion of an image model from an image model database, while the input 110 include at least a portion of image data acquired by at least an image sensor. In the meantime, the pattern-processing circuit 180 performs pattern recognition between the image model and the image data.

Accordingly, the present invention discloses an image-recognition processor, comprising: an input for transferring at least a portion of image data; a semiconductor substrate having transistors thereon; a plurality of storage-processing units (SPU) coupled with said input, each of said SPUs comprising at least a three-dimensional memory (3D-M) array and a pattern-processing circuit, wherein said 3D-M array is stacked above said pattern-processing circuit and stores at least a portion of an image model; said pattern-processing circuit is disposed on said semiconductor substrate and performs pattern recognition between said image model and said image data; said 3D-M array and said pattern-processing circuit are communicatively coupled by a plurality of contact vias.

H) Image Storage with In-Situ Image-Searching Capabilities.

It is highly desired to search an image database for an image pattern. The image database includes a plurality of image files. When it is to be stored permanently, the image database becomes an image archive. On the other hand, the image pattern includes an image segment such as an object, a feature or an activity. The image pattern could also include an image model. It is challenging to do image-search for a conventional computer because of the von Neumann architecture.

To address this issue, the present invention discloses an image storage with in-situ image-searching capabilities. It takes the form of a pattern storage with in-situ pattern-processing capabilities. To be more specific, the 3D-M array 170 permanently stores at least a portion of image data from an image database, while the input 110 includes at least a portion of an image pattern. In the meantime, the pattern-processing circuit 180 performs pattern recognition between the image pattern and the image data. With massive parallelism and fast ISP-connections, the preferred image storage can perform image-searching operations on its image data fast and efficiently.

Accordingly, the present invention discloses an image storage with in-situ image-searching capabilities, comprising: an input for transferring at least a portion of an image pattern; a semiconductor substrate having transistors thereon; a plurality of storage-processing units (SPU) coupled with said input, each of said SPUs comprising a pattern-processing circuit and at least a three-dimensional memory (3D-M) array, wherein said 3D-M array is stacked above said pattern-processing circuit and stores at least a portion of image data; said pattern-processing circuit is disposed on said semiconductor substrate and performs pattern recognition between said image pattern and said image data; said 3D-M array and said pattern-processing circuit are communicatively coupled by a plurality of contact vias.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A data storage with in-situ string-searching capabilities, comprising:
an input for transferring at least a search string;
a semiconductor substrate having transistors thereon;
a plurality of storage-processing units (SPU) coupled with said input, each of said SPUs comprising a pattern-processing circuit and at least a three-dimensional vertical memory (3D-M_{V}) array, wherein
said 3D-M_{V} array is stacked above said pattern-processing circuit and stores at least a portion of data;
said pattern-processing circuit is disposed on said semiconductor substrate and searches said search string in said portion of data;
said 3D-M_{V} array and said pattern-processing circuit are communicatively coupled by a plurality of contact vias.

2. The data storage according to claim 1, wherein said 3D-M_{V} is three-dimensional writable memory (3D-W).

3. The data storage according to claim 2, wherein said 3D-W is three-dimensional one-time-programmable memory (3D-OTP).

4. The data storage according to claim 2, wherein said 3D-W is three-dimensional multiple-time-programmable memory (3D-MTP).

5. The data storage according to claim 1, wherein said 3D-M_{V} comprises two-terminal devices.

6. The data storage according to claim 5, wherein said two-terminal devices comprise diodes or diode-like devices.

7. The data storage according to claim 1, wherein said 3D-M_{V} comprises three-terminal devices.

8. The data storage according to claim 7, wherein said three-terminal devices comprise transistors or transistor-like devices.

9. The data storage according to claim 1, wherein said pattern-processing circuit comprises at least a text-matching circuit.

10. The data storage according to claim 1, wherein said pattern-processing circuit comprises at least a string-matching circuit.

11. The data storage according to claim 1, wherein said pattern-processing circuit comprises at least a code-matching circuit.

12. The data storage according to claim 1, wherein said pattern-processing circuit comprises at least a finite-state automata (FSA) circuit.

13. The data storage according to claim 1, wherein said pattern-processing circuit comprises at least a sorting function.

14. The data storage according to claim 1, wherein said pattern-processing circuit comprises at least a filtering function.

15. The data storage according to claim 1, wherein said pattern-processing circuit comprises at least a malware-screening function.

16. The data storage according to claim 1, wherein a preliminary pattern processing is performed at said data storage.

17. The data storage according to claim 16, wherein a full pattern processing is performed at an external processor.

18. The data storage according to claim 1, wherein said data storage is a portion of a storage card.

19. The data storage according to claim 1, wherein said data storage is a portion of a solid-state drive.

20. The data storage according to claim 1, wherein said 3D-M_{V} array at least partially covers said pattern-processing circuit.
